(19) United States
(12) Patent Application Publication
(10) Pub. No.: US 2014/0305590 A1
(43) Pub. Date: Oct. 16, 2014

(54) NON-PLASMA DRY ETCHING APPARATUS

(71) Applicant: Panasonic Corporation, Osaka (JP)

(72) Inventors: NAOSHI YAMAGUCHI, Osaka (JP); HIROSHI TANABE, Nara (JP); YASUSHI TANIGUCHI, Osaka (JP)

(73) Assignee: PANASONIC CORPORATION, Osaka (JP)

(21) Appl. No.: 14/251,646

(22) Filed: Apr. 14, 2014

(30) Foreign Application Priority Data
Apr. 16, 2013 (JP) 2013-085400
Feb. 12, 2014 (JP) 2014-024020

(51) Int. Cl. H01L 31/18

(52) U.S. Cl. CPC H01L 31/1804
USPC 156/345.29

(57) ABSTRACT

A non-plasma dry etching apparatus forms textures by processing plural substrates at the same time, and all substrates and textures in respective substrate planes are formed to be uniform at the time of processing and all substrates and values of the reflectance in respective substrate planes are formed to be uniform as well as size reduction of equipment. The substrates are placed in plural stages so as to be parallel to the flow of a process gas in a reaction chamber. The uniform etching is realized by installing turbulent flow generation blades in the upstream side of the flow.

### BACKGROUND OF THE INVENTION

1. Field of the Invention

The present invention relates to a non-plasma dry etching apparatus.

2. Description of Related Art

In silicon solar cells (photoelectric conversion devices), projections and depressions called textures are provided on a light receiving surface of a silicon substrate to thereby suppress the reflection of incident light on the light receiving surface as well as prevent the light taken into the silicon substrate from being leaked out.

The formation of textures is generally performed by a wet process using an aqueous alkaline (KOH) solution as an etchant. The formation of textures by the wet process requires a washing process using hydrogen fluoride, a heat process and the like as post processes. Accordingly, there is a danger of contaminating the surface of the silicon substrate and the process is disadvantageous also on the aspect of costs.

On the other hand, methods of forming textures on the surface of the silicon substrate by a dry process have been also proposed. For example, there are proposed (1) a method of using a reactive ion etching by plasma and (2) a method of etching the surface of the silicon substrate by introducing any of gases of ClF₃, XeF₂, BrF₃ and BrF₅ into a reaction chamber in which the substrate has been placed under atmospheric pressure (refer to JP-A-10-313128 (Patent Document 1)).

As equipment for mass production by the above method (2), a dry-etching apparatus in which a movable stage is provided in a reaction chamber, an etching gas is injected toward silicon substrates placed on the stage to process the plural silicon substrates continuously while moving the stage has been also proposed (for example, refer to JP-A-2012-186283 (Patent Document 2)).

FIG. 23 is a view of an apparatus for realizing the etching-method described in Patent Document 1.

Silicon substrates 3 are placed on a stage 2 in a standing manner in a reaction chamber 1. The reaction chamber 1 maintains a given pressure by exhausting a process gas 8 by a vacuum pump 5 while adjusting the pressure by a pressure regulating valve 4. The process gas 8 includes an N₂ gas as a dilution gas and any of gases of ClF₃, XeF₂, BrF₃ and BrF₅ stored in a gas cylinder 6 as a reaction gas.

The process gas 8 is fed to the reaction chamber 1 through a mass-flow controller 7. In the reaction chamber 1, the silicon substrates 3 react with the process gas 8 and fine projections and depressions can be formed on surfaces of the silicon substrates to thereby form textures for the solar cells.

An apparatus proposed as a manufacturing apparatus for mass production by applying the above technique is a manufacturing apparatus described in Patent Document 2, which is shown in FIG. 24.

A reaction chamber 1 is connected to a load lock chamber 9 and an unload lock chamber 10, and a tray-shaped stage 2 on which silicon substrates 3 are placed moves through rollers 11. When the stage 2 moves through the rollers 11, a gas formed by mixing the N₂ gas as a dilution gas with any of gases of ClF₃, XeF₂, BrF₃ and BrF₅ as a reaction gas is injected as a process gas 8 by blade-shaped nozzles 12, and a cooling gas is injected by blade-shaped nozzles 13 at the same time.

As the silicon substrates 3 are exposed to the process gas 8, the silicon substrates 3 react with the process gas 8 and fine projections and depressions are formed on surfaces of the silicon substrates.

### SUMMARY OF THE INVENTION

However, it has been found by the writer et al. that it is difficult to form uniform textures on all the silicon substrates placed on the tray by the manufacturing apparatus for the mass production in the related-art structure shown in Patent Document 2.

FIG. 25 is a graph showing the relation between the size of formed textures and the ClF₃ gas density obtained when single-crystal silicon substrates having a plane orientation (111) are etched using the ClF₃ gas as a process gas and the N₂ gas as a dilution gas by the writer et al.

In the drawing, it is found that the texture size is increased as the ClF₃ gas density is increased. The texture size is represented as the height difference of formed projections and depressions.

FIG. 26 is a graph showing the relation between the size of formed textures and the reflectance of silicon substrates with textures obtained at that time. In the drawing, it is found that the reflectance is reduced as the texture size is increased.

The above findings indicate that, when the plane of the silicon substrate is exposed to the process gas at a non-uniform density, portions in which the reflectance is locally high are formed. Then, in the related-art structure shown in Patent Document 2, it is also found that the density of the process gas to which the silicon substrates 3 are exposed is not uniform in the reaction charmer 1.

FIG. 27 is a view shown by enlarging portions of components of the blade-shaped nozzles 12, the blade-shaped nozzles 13, the tray-shaped stage 2 and the silicon substrates 3 in Patent Document 2. The findings of the writer et al. will be explained with reference to the drawing.

In the case where the process gas 8 is injected from the blade-shaped nozzles 12 and a cooling gas 14 is injected from the blade-shaped nozzles 13, portions A surrounded by dotted lines in FIG. 27 are right below the blade-shaped nozzles 12, which are portions where the density of the process gas 8 is relatively high.

On the other hand, portions B surrounded by dotted line are right below the blade-shaped nozzles 13, which are portions where the density of the cooling gas 14 is relatively high. Portions C surrounded by dotted lines are portions where gas injections of the process gas 8 and the cooling gas 9 intersect each other. When the portions are sectioned as A, B and C for convenience sake, the densities of the process gas are represented as “portions A surrounded by dotted lines>portions C surrounded by dotted lines>portions B surrounded by dotted lines” in ascending order of densities.

When the stage 2 moves with the silicon substrate 3 placed thereon under the above conditions as shown in FIG. 27, the silicon substrates 3 move while being exposed alternately to portions where the density of the process gas is high and the portions where the density of the process gas is low. In this case, it is difficult that respective plural silicon substrates 3 are exposed to a fixed density of the process gas.

Specifically, the process gas 8 injected from the blade-shaped nozzles 12 and the cooling gas 14 injected from the blade-shaped nozzles 13 are not mixed on the surface of the silicon substrate 3, which locally create the portions where the density of the process gas is high and portions where the density is low in some cases. As a result, it is difficult to form uniform textures in the plane of the silicon substrate 3 and to realize uniform reflectance on the plane of the substrate.

Conversely, in order to prevent portions with the high density of the process gas and portions with the low density from being locally created, a large distance can be set between the silicon substrate 3 and the blade-shaped nozzle 12 and the blade-shaped nozzle 13. Accordingly, the process gas 8 and the cooling gas 14 are diffused before reaching the silicon substrate 3, therefore, the process gas 8 and the cooling gas 14 can be uniformly mixed. However, the cooling effect of the cooling gas 14 itself may be reduced.

Furthermore, the manufacturing apparatus of Patent Document 2 has the structure in which plural silicon substrates 3 are placed on the stage 2 in a flat manner. Therefore, a large installation area is necessary for the equipment, which will be a problem as the equipment for mass production.

The present invention has been made for solving the above problems, and an object thereof is to provide a non-plasma etching apparatus processing plural substrates at the same time, capable of processing the plural substrates uniformly in respective substrate planes, and realizing the reduction of the installation area for equipment.

In order to achieve the above object, the present invention has the following characteristics:

(1) a reaction chamber which can perform vacuum pumping,

(2) a feed opening connected to the reaction chamber to feed a process gas,

(3) an exhaust opening connected to the reaction chamber to exhaust the gas in the reaction chamber as well as arranged so as to face the feed opening,

(4) a substrate holding mechanism arranged between the feed opening and the exhaust opening to hold substrates,

(5) wherein in the substrate holding mechanism, surfaces on which the substrates are placed are arranged in parallel to a flow direction of the process gas fed from the feed opening, and

(6) a blade-shaped turbulent flow generation mechanism or one to plural wires or bars, provided close to an edge portion near the feed opening of each substrate.

According to the above structure, the process gas flows in one direction in a parallel flow state from the process gas feed opening to the process gas exhaust opening in the reaction chamber. As the plural substrates are installed in the substrate holding mechanism so as to be parallel to the flow direction of the process gas, a chemical reaction is realized while the process gas flows along substrate planes from the process gas feed opening as the upstream side toward the process gas exhaust opening as the downstream side.

Generally, when a flat plate is placed in the gas flow of one direction so as to be parallel to the flow direction as shown in FIG. 28, a boundary layer is formed from an edge of the upstream side of the flat plate to the downstream direction. The boundary layer is developed along the travel of the flow, and the thickness of the boundary layer is increased. The boundary layer changes from a laminar flow boundary layer into a turbulent flow boundary layer from the upstream side to the downstream side of the flow, and a state in the middle of the change from the laminar flow boundary layer to the turbulent flow boundary layer is called a transition area.

When the flat plate is regarded as the silicon substrate and the gas in the gas flow is regarded as the process gas, the behavior of reaction products in the chemical reaction inside the laminar flow boundary layer is as shown in FIG. 29 and the behavior of reaction products in the chemical reaction inside the turbulent flow boundary layer is as shown in FIG. 30.

As shown in FIG. 29, the gas flow is only in a direction parallel to the silicon substrate and there is little gas flow in a direction perpendicular to the silicon substrate in the laminar flow boundary layer, therefore, the movement of substances hardly occurs in the direction perpendicular to the silicon substrate.

Accordingly, on the surface of the silicon substrate, reaction products generated by the chemical reaction between the process gas and the silicon substrate flow in the downstream side of the gas flow in the vicinity of the surface of the silicon substrate. However, the movement of substances hardly occurs in the direction perpendicular to the silicon substrate planes as described above, so that the density of reaction products is increased on the surface of the silicon substrate as coming close to the downstream and the density of the process gas is relatively reduced.

Accordingly, there occurs a phenomenon in which the chemical reaction is active in the upstream side and the chemical reaction is relatively inactive in the downstream side and the proceeding degree of etching varies in the laminar flow boundary layer.

On the other hand, as shown in FIG. 30, the gas flow in the turbulent flow boundary layer is uniform from the upstream to the downstream on average, but the gas flow is microscopically a turbulent flow in which irregular flows are constantly generated. The movement of substances occurs in the direction perpendicular to the silicon substrate.

Accordingly, the reaction products generated by the chemical reaction between the process gas and the silicon substrate are interchanged with the process gas positively on the surface of the silicon substrate. Accordingly, there occurs a phenomenon in which the chemical reaction is active both in the upstream side and the downstream side, and the proceeding degree of etching is uniform in the turbulent flow boundary layer. That is, in the case where the turbulent flow boundary layer is generated over the entire surface of the silicon substrate, the chemical reaction is active and the proceeding degree of etching is uniform over the entire surface of the silicon substrate.

As a mechanism for generating the turbulent flow over the entire surface of the silicon substrate, the turbulent flow generation mechanism is installed close to the edge of the silicon substrate in the upstream side of the flow as shown in FIG. 1B in the present invention.

Accordingly, as the gas flow already becomes turbulent before reaching the silicon substrate, the proceeding degree of chemical reaction in the substrate plane can be uniform over the entire surface of the silicon substrate from the upstream side to the downstream side.

As a result, the proceeding degree of etching can be uniform in all the plane of the silicon substrate, thereby forming the texture size to be uniform and the reflectance in the entire substrate can be uniformed. As plural silicon substrates are installed to face to one another in the reaction chamber, the installation area of the dry etching apparatus can be largely reduced.

As described above, when the non-plasma dry etching apparatus according to the present invention is applied, surfaces of plural substrates can be uniformly etched so that it can respond to mass production. As the plural substrates are installed to face one another in the reaction chamber, the installation area of the dry etching apparatus can be largely reduced.

### BRIEF DESCRIPTION OF THE DRAWINGS

FIG. 1A is a view showing a non-plasma dry etching apparatus for mass production according to Embodiment 1 of the present invention, and FIG. 1B is a schematic view of a turbulent flow generation mechanism and a gas flow of the non-plasma dry etching apparatus for mass production according to Embodiment 1 of the present invention;

FIG. 2 is a view showing an example of a process gas feed opening according to Embodiment 1 of the present invention;

FIG. 3 is a view showing an example of a process gas feed opening according to Embodiment 1 of the present invention;

FIG. 4 is view showing an example of a process gas feed opening according to Embodiment 1 of the present invention;

FIG. 5 is a view showing an example of a substrate holding mechanism according to Embodiment 1 of the present invention;

FIG. 6 is a view showing an example of a turbulent flow generation mechanism according to Embodiment 1 of the present invention;

FIG. 7 is a view showing an example of a turbulent flow generation mechanism according to Embodiment 1 of the present invention;

FIG. 8 is a view showing an example of a turbulent flow generation mechanism according to Embodiment 1 of the present invention;

FIG. 9 is a view showing an example of a turbulent flow generation mechanism according to Embodiment 1 of the present invention;

FIG. 10 is a view showing an example of a turbulent flow generation mechanism according to Embodiment 1 of the present invention;

FIG. 11 is a view showing an example of a turbulent flow generation mechanism according to Embodiment 1 of the present invention;

FIG. 12 is a view showing an example of a turbulent flow generation mechanism according to Embodiment 1 of the present invention;

FIG. 13 is a view showing an example of a turbulent flow generation mechanism according to Embodiment 1 of the present invention;

FIG. 14 is a view showing the arrangement of substrates and measurement points in a dry etching experiment according to Embodiment 1 of the present invention;

FIG. 15 is a graph showing results obtained by measuring the texture size and the reflectance in the dry etching experiment according to Embodiment 1 of the present invention;

FIG. 16 is a view showing a non-plasma dry etching apparatus for mass production according to Embodiment 2 of the present invention;

FIG. 17 is a schematic view showing a gas flow and a viscous sublayer on a flat plate;

FIG. 18 is a schematic view showing turbulent flow guide plates and a gas flow in the non-plasma dry etching apparatus for mass production according to Embodiment 2 of the present invention,

FIG. 19 is a view showing a non-plasma dry etching apparatus for mass production according to Embodiment 3 of the present invention;

FIG. 20 is a schematic view showing a gas flow in the non-plasma dry etching apparatus for mass production according to Embodiment 3 of the present invention;

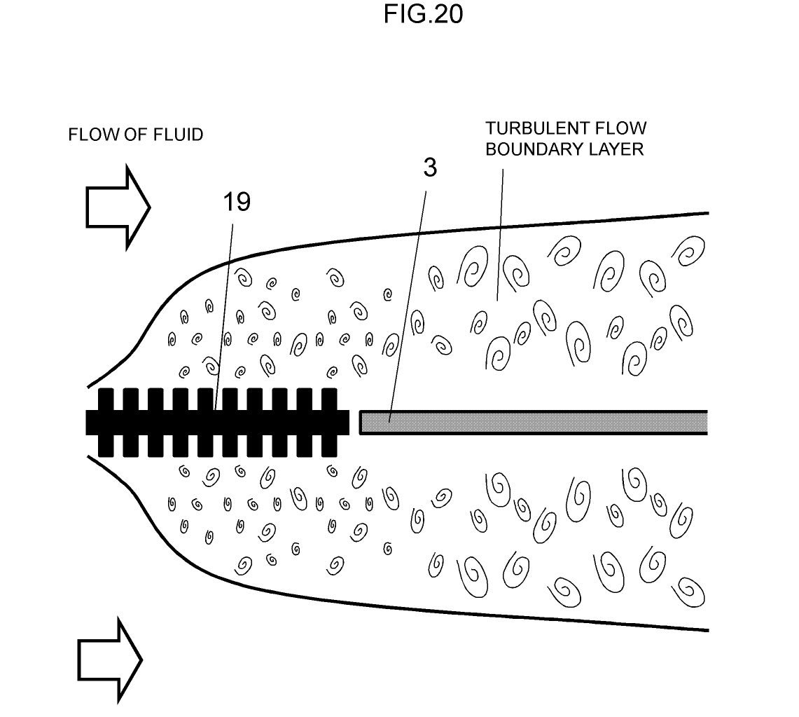

FIG. 21 is a view showing an example of a substrate holding mechanism according to Embodiment 3 of the present invention;

FIG. 22 is a view showing a non-plasma dry etching apparatus for mass production according to Embodiment 4 of the present invention;

FIG. 23 is a view showing a related-art non-plasma dry etching apparatus described in Patent Document 1;

FIG. 24 is a view showing a related-art non-plasma dry etching apparatus for mass production described in Patent Document 2;

FIG. 25 is a graph showing the relation between the texture size and the ClF₃ gas density;

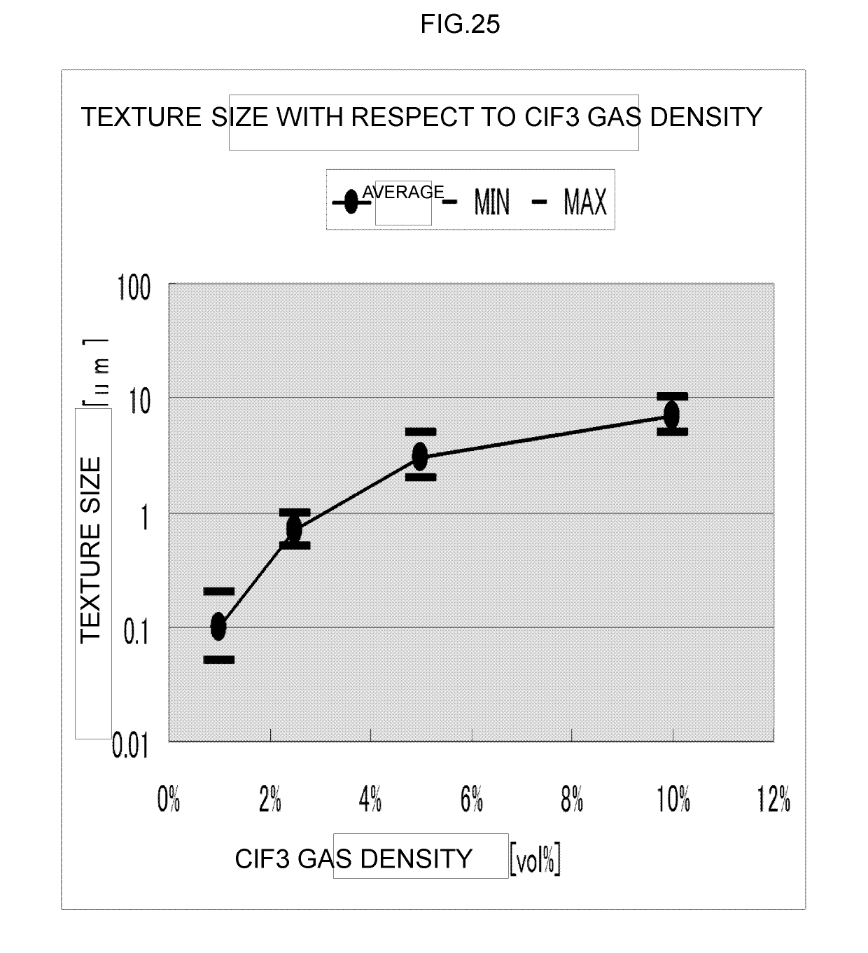

FIG. 26 is a graph showing the relation between the texture size and the substrate reflectance;

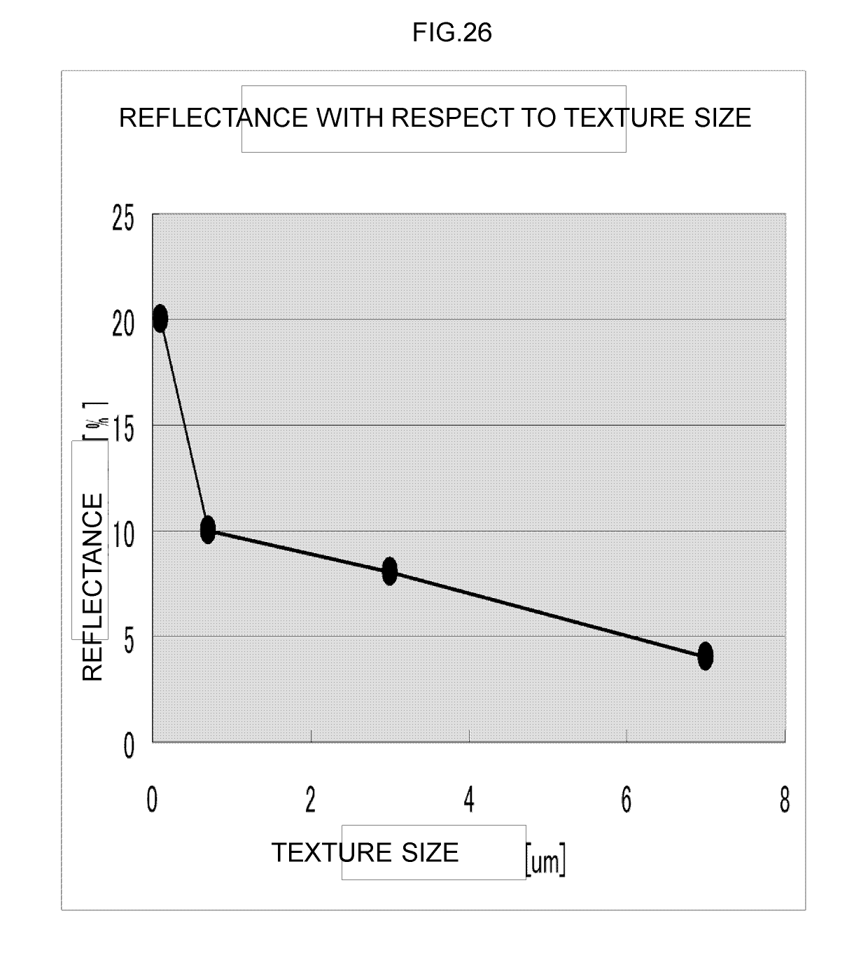

FIG. 27 is an enlarged view in a reaction chamber of a related-art non-plasma dry-etching apparatus for mass production described in Patent Document 2;

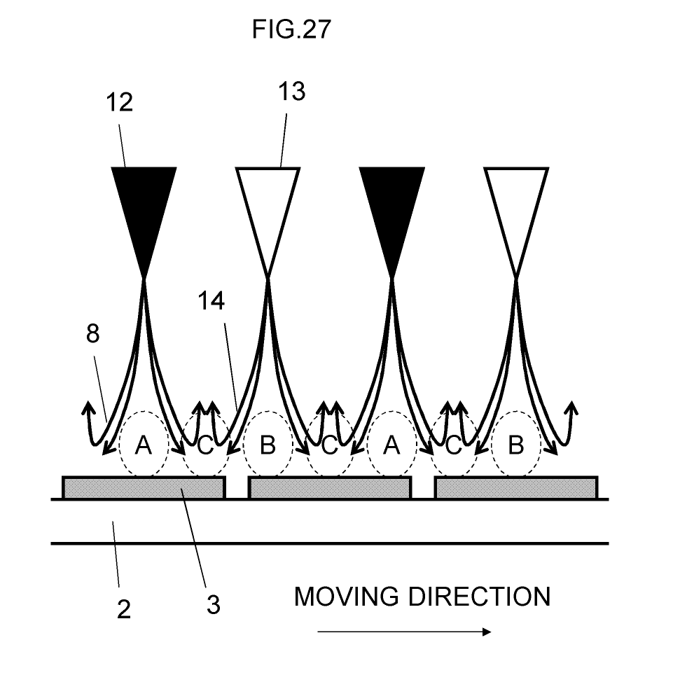

FIG. 28 is a schematic view showing a gas flow on a flat plate;

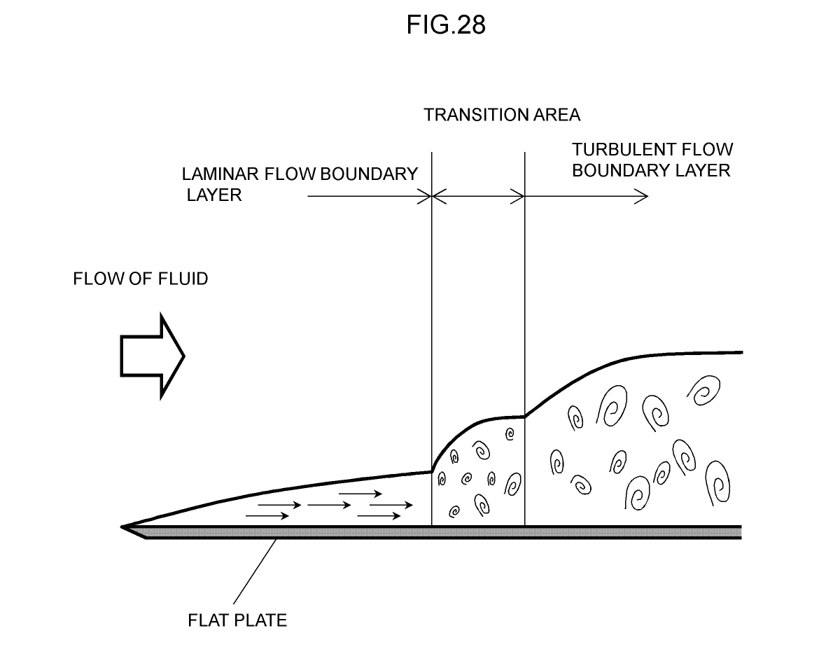

FIG. 29 is a schematic view showing a gas flow and chemical reaction in a laminar flow boundary layer on a flat plate; and

FIG. 30 is a schematic view showing a gas flow and chemical reaction in a turbulent flow boundary layer on a flat plate.

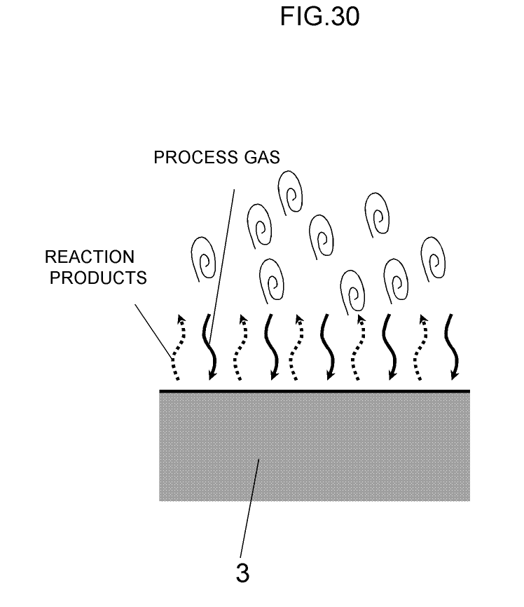

### DESCRIPTION OF PREFERRED EMBODIMENTS

Hereinafter, embodiments of the present invention will be explained with reference to the drawings.

### Embodiment 1

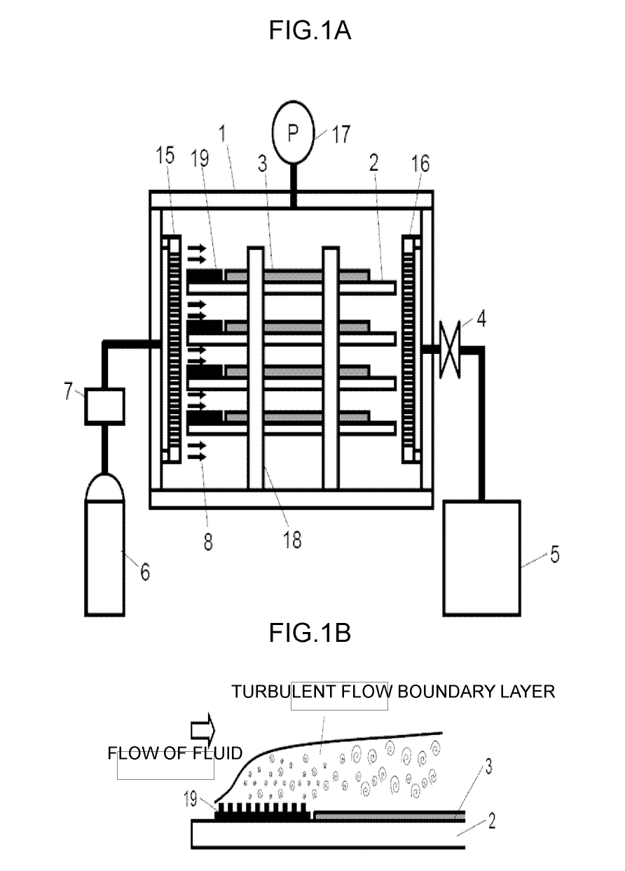

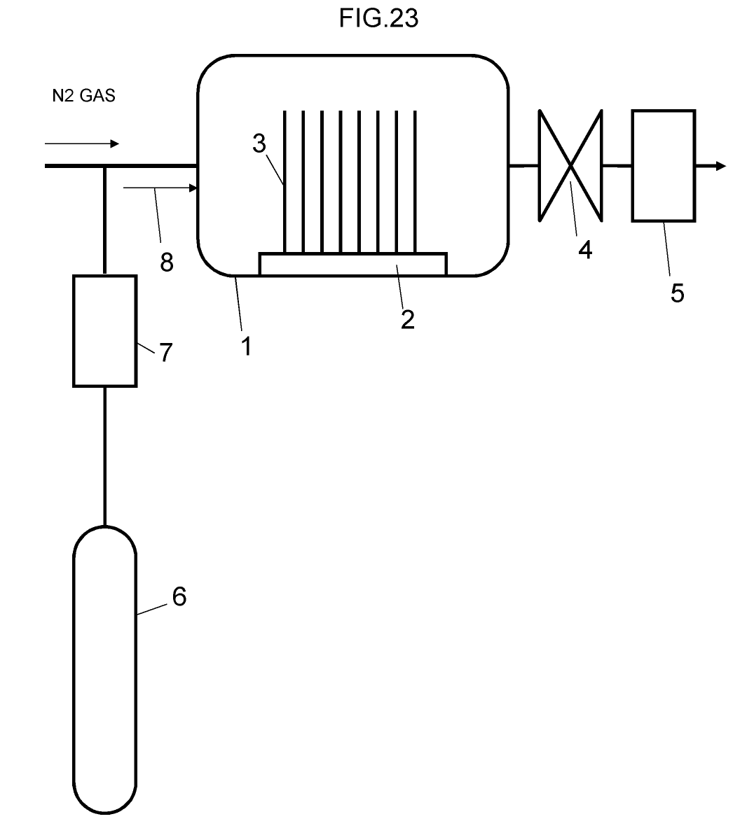

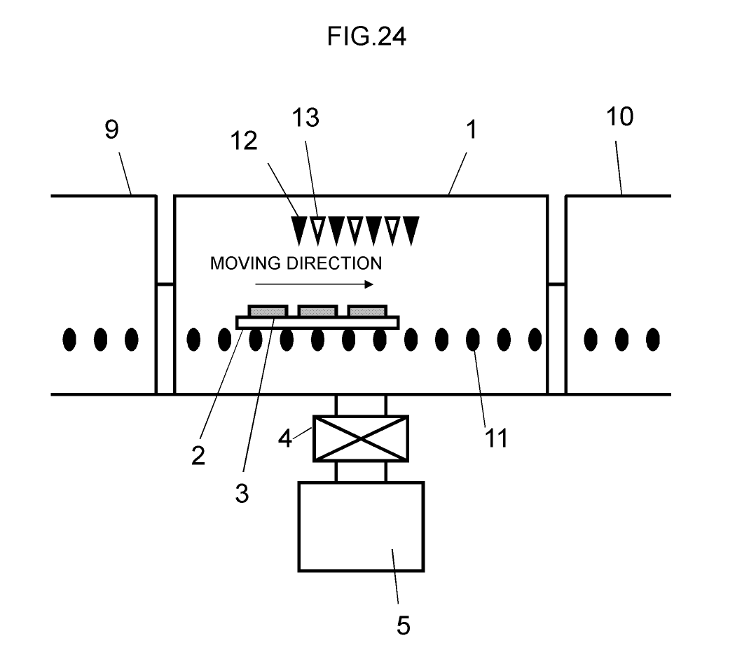

FIG. 1A is a view showing a non-plasma dry etching apparatus according to Embodiment 1 of the present invention. In FIGS. 1A and 1B, the same components as in FIG. 23 and FIG. 24 are denoted by the same numerals and the explanation thereof is omitted.

As shown in FIG. 1A, the non-plasma dry etching apparatus according to the present embodiment is provided with a process gas feed opening 15 and a process gas exhaust opening 16 facing each other in the reaction chamber 1 which can perform vacuum pumping. Both the process gas feed opening 15 and the process gas exhaust opening 16 have a shower plate structure for realizing uniform flow.

According to the above structure, the uniform parallel flow of the process gas is realized from the process gas feed opening 15 to the process gas exhaust opening 16. Moreover, a given pressure is maintained in the reaction chamber 1 by the pressure regulating valve 4 and the vacuum pump 5 while monitoring the pressure in the reaction chamber 1 by a pressure gauge 17.

Plural silicon substrates 3 are placed on stages 2 one by one. Respective silicon substrates 3 are placed in parallel to the flow of the process gas so as to face one another by a substrate holding mechanism 18. Moreover, a turbulent flow generation mechanism 19 is installed close to an edge of the substrate arranged on the upstream side of the process gas in each silicon substrate 3 as shown in FIG. 1B, which is a structure in which turbulent flow is generated over the entire substrate plane.

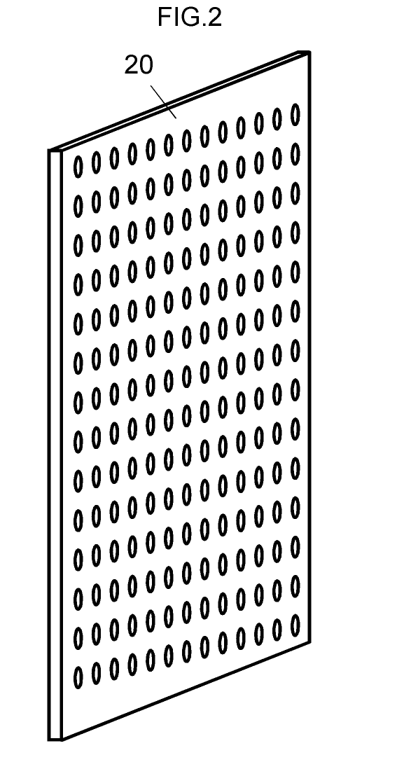

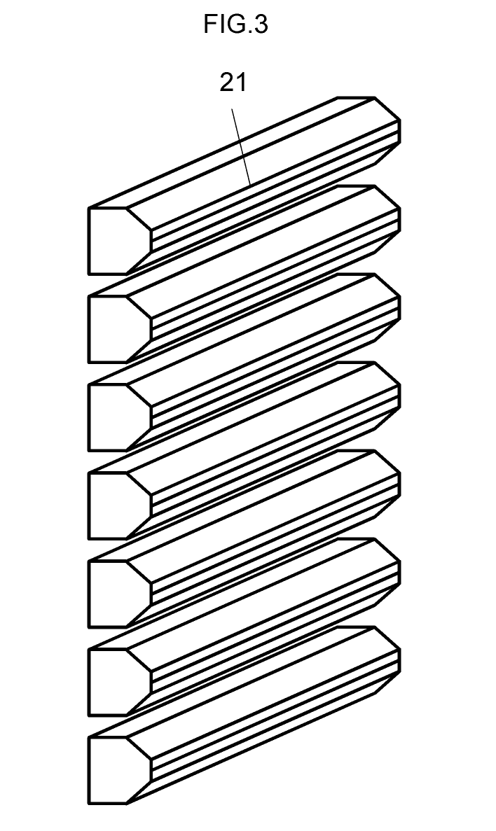

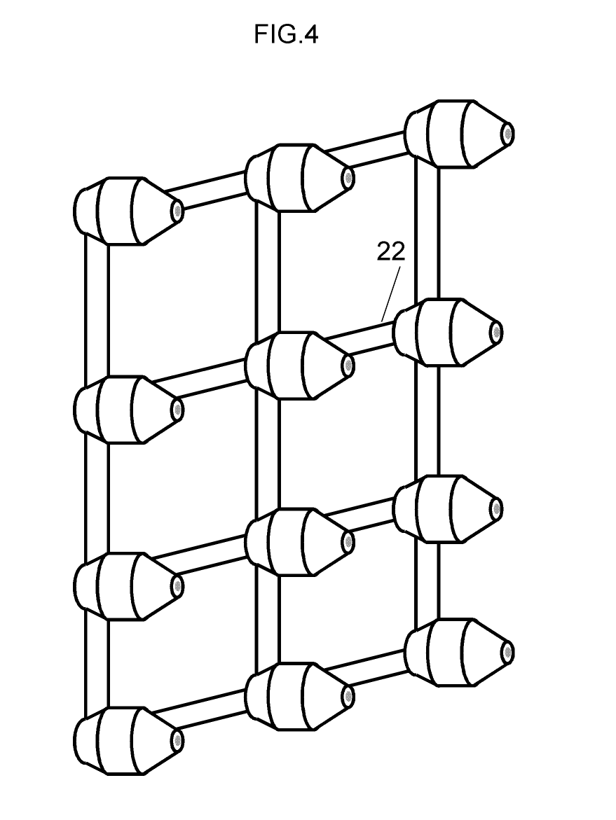

The process gas feed opening 15 may be any structure in which the uniform parallel flow can be realized, and for example, a shower plate 20 having innumerable fine pores as shown in FIG. 2 or a structure in which plural slit nozzles 21 are aligned as shown in FIG. 3 can be applied. It is also possible to apply a structure in which plural spray nozzles 22 are aligned in a matrix as shown in FIG. 4.

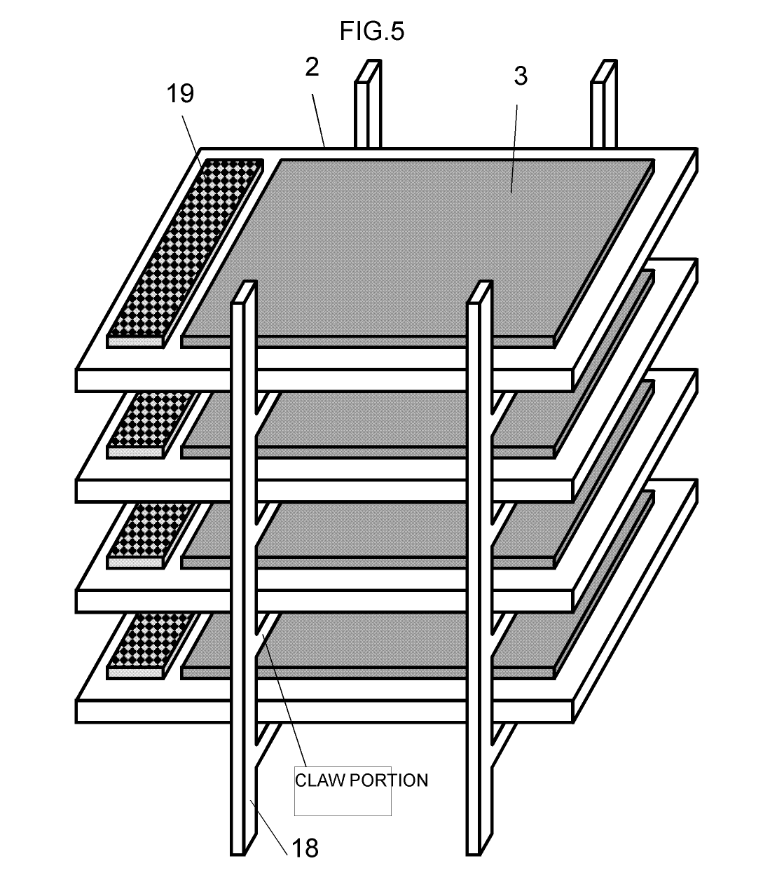

The substrate holding mechanism 18 may be any structure in which the process gas can pass from the upstream side to the downstream side of the silicon substrates 3, and for example, a structure in which both ends of the stages 2 on which the silicon substrates 3 are placed are held by claws arranged at equal intervals is preferable as shown in FIG. 5.

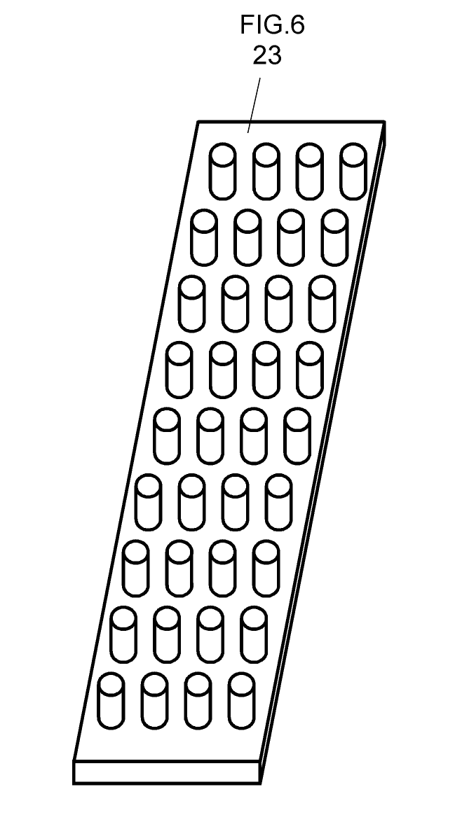

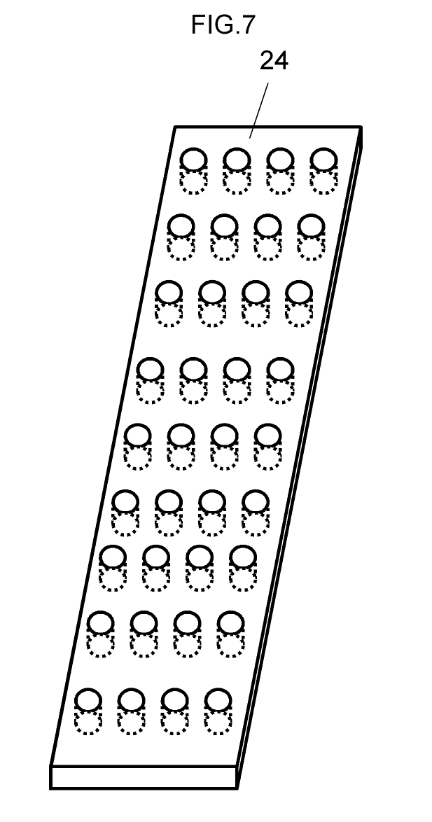

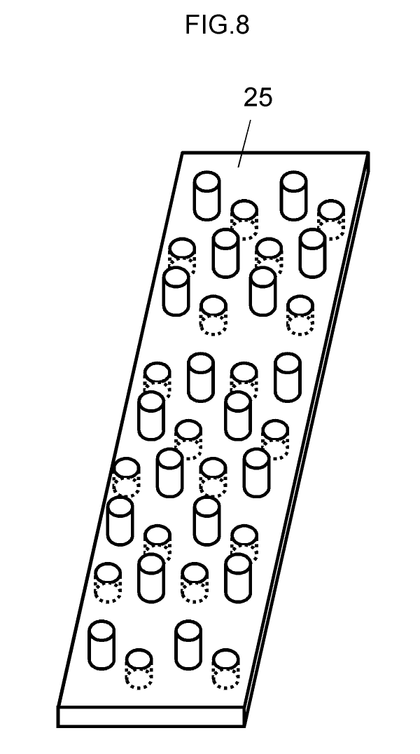

The turbulent flow generation mechanism 19 may be any structure in which the turbulent flow can be efficiently generated, and for example, a blade 23 having innumerable projections as shown in FIG. 6, a blade 24 having innumerable depressions or pores as shown in FIG. 7 or a blade 25 having innumerable projections and depressions or pores alternately as shown in FIG. 8 can be applied.

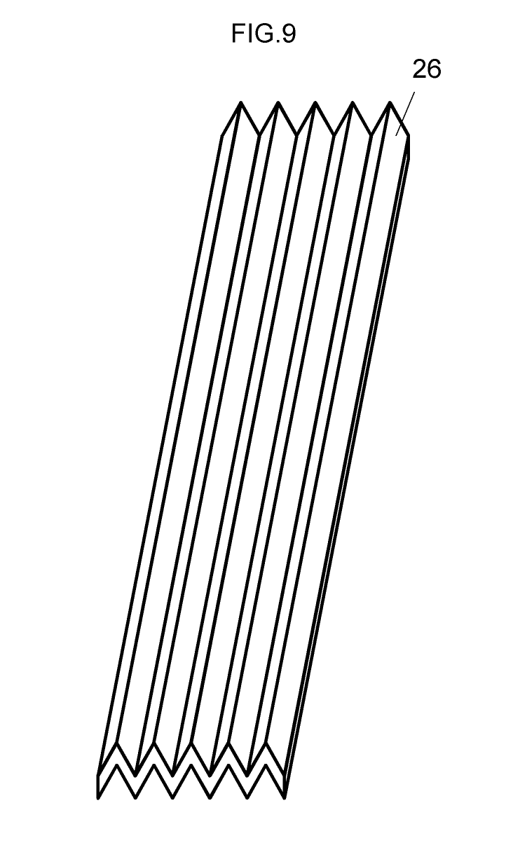

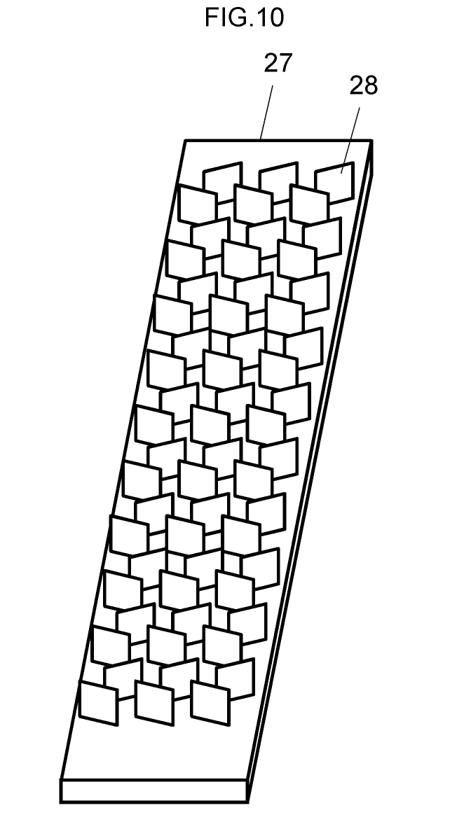

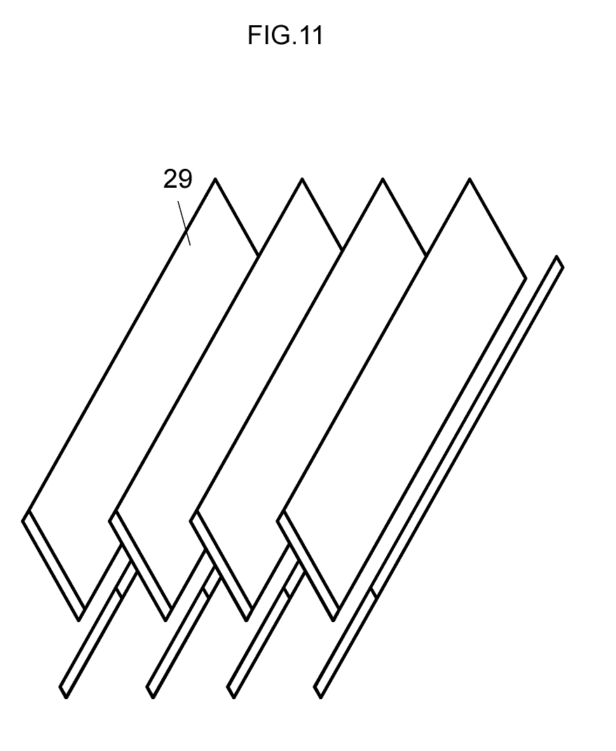

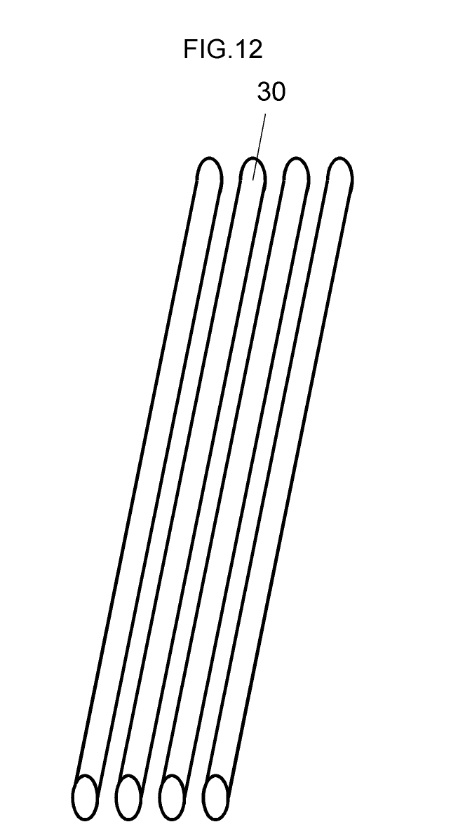

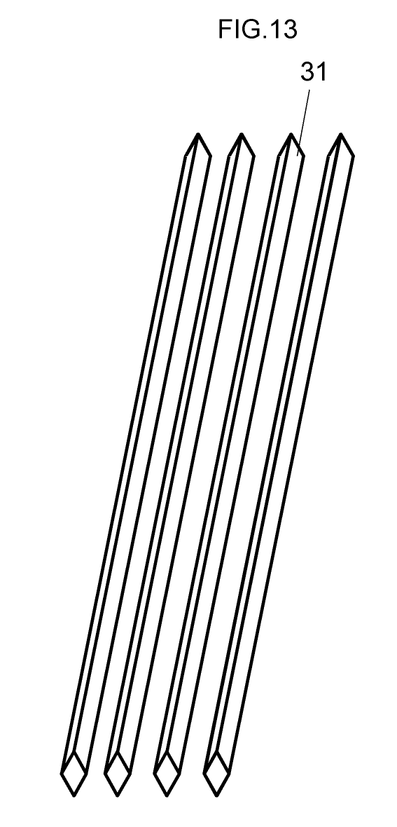

It is further possible to apply a blade 26 having a rectangular corrugated shape as shown in FIG. 9, a structure in which second wings 28 are vertically provided over a first wing 27 so that the second wings 28 are alternately arranged at angles as shown in FIG. 10, or a structure in which plural blades 29 are alternately arranged with an angle of elevation with respect to the upstream side of the process gas as shown in FIG. 11. Furthermore, it is not always necessary that the turbulent flow generation mechanism is the blade-shaped type, but it is possible to apply a structure in which one or plural wires or bars 30 having a circular cross section as shown in FIG. 12 are placed or a structure in which wires or bars 31 having a polygonal cross section as shown in FIG. 13 are placed.

According to the above structures, the process gas 8 which has become turbulent with respect to respective silicon substrates 3 by the turbulent flow generation mechanisms 19 can pass through the surfaces of respective silicon substrates 3 in a turbulent state. When the process gas 8 which has become turbulent passes, a given chemical reaction is promoted, and reaction products generated by the chemical reaction between the process gas 8 and the silicon substrates 3 are efficiently interchanged, as a result , uniform etching is performed over the entire surfaces of respective silicon substrates 3.

Accordingly, the plural silicon substrates 3 can be uniformly exposed to the gas with the same density, and the surfaces of all silicon substrates 3 can be uniformly etched. For example, in the case of silicon substrates for solar cells, it is possible to uniform the texture size and to uniform the reflectance of all silicon substrates 3.

### EXAMPLE

Four silicon substrates with a plane orientation (111) were arranged so as to face one another in the substrate holding mechanism 18, and etching processing was performed under conditions in which a gas formed by mixing the N₂ gas as a dilution gas with the ClF₃ gas: 5% and the O₂ gas: 20% with respect to the N₂ gas was used as the process gas 8 and the pressure inside the reaction chamber 1 was 90 kPa.

Here, a mechanism in which the silicon substrates with the plane orientation (111) are exposed to the mixed gas including ClF₃ and O₂ to perform dry etching without generating plasma will be explained.

The above mechanism is interpreted as the following chemical reaction by the study of the writer et al.

3Si+4ClF₃→3SiF₄↑+2Cl₂↑ (A)

Si+O₂→SiO₂ (B)

When the silicon substrate is exposed to the ClF₃ gas, ClF₃ is decomposed and silicon reacts as represented by the chemical reaction formula (A) to be SiF₄. As SiF₄ is a gas, it is separated from the silicon substrate.

On the other hand, as O₂ exists in the mixed gas, SiO₂ is microscopically formed as represented by the chemical reaction (B) as the etching proceeds by the chemical reaction (A). As SiO₂ does not react with ClF₃ and is not etched, the microscopically-formed SiO₂ becomes a self mask to allow the etching along the plane orientation to proceed therefrom. When the surface exposed to the mixed gas is a (111) plane, textures having etch pits surrounded by three planes of a (100) plane, a (010) plane and a (001) plane are formed.

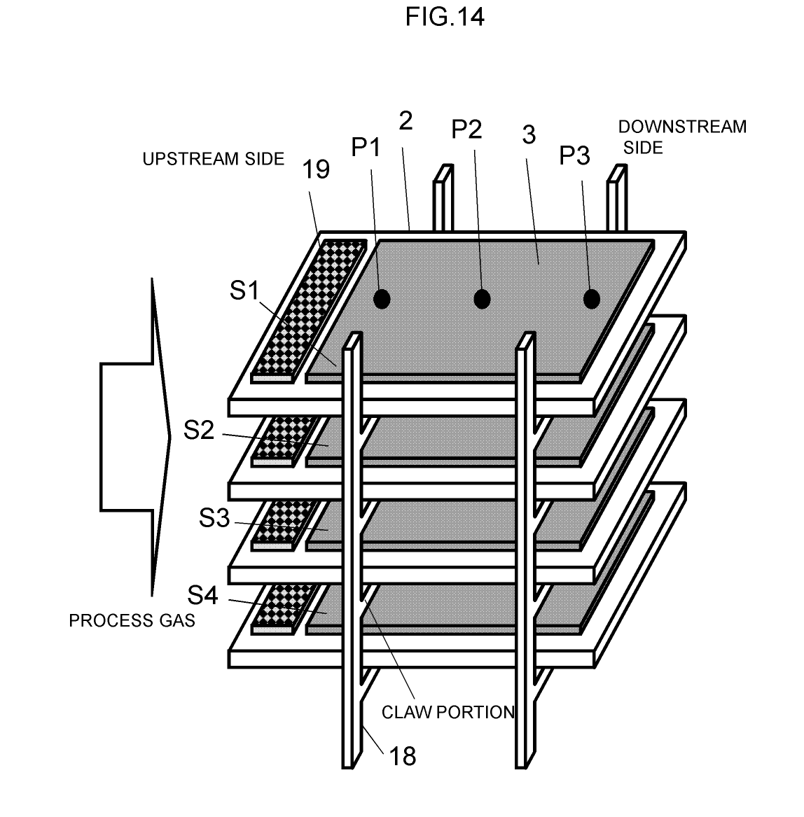

FIG. 14 is a view showing the arrangement of substrates and measurement points in the dry etching experiment.

As shown in the drawing, four silicon substrates 3 were placed on stages 2 in the substrate holding mechanism 18 so as to face one another. Note that four silicon substrates 3 are denoted by S1, S2, S3 and S4 from an upper stage for convenience. Measurement points in the silicon substrates 3 of S1 to S4 are denoted by P1 as the center of an upstream-side substrate edge portion, P2 as the substrate center portion and P3 as the center of a down-stream substrate edge portion in each substrate.

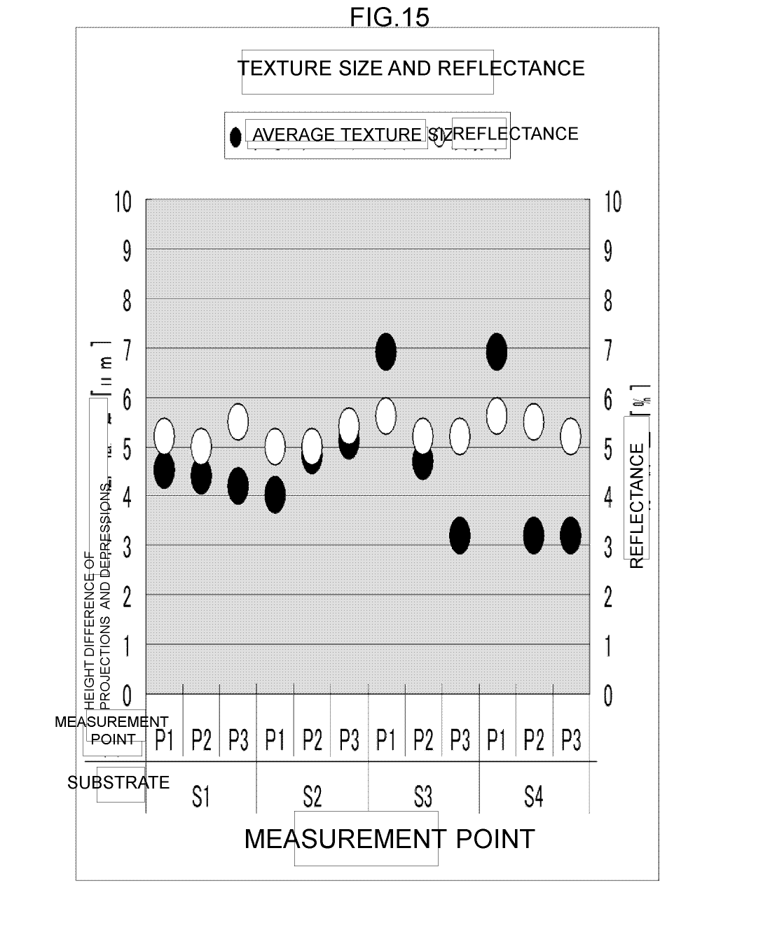

A graph obtained by measuring the texture size and the reflectance in the above all measurement points is shown in FIG. 15.

The measured texture size was obtained by observing a substrate cross section at each measurement point with a magnification of 5000× using an electron microscope, measuring 10 projections and depressions observed in one visual field at random and calculating an average value of height differences of respective projections and depressions. The reflectance was obtained by measuring each measuring point by a spectrophotometer, extracting a reflectance in a wavelength 600 nm as a representative value from obtained profiles to make comparison.

As the turbulent flow generation mechanism 19, the blade 24 having innumerable depressions as shown in FIG. 7 was used.

In FIG. 15, values of the texture size almost fall into a range between 3.2 to 6.9 UM in average, and the size is uniformed. Values of the reflectance also fall into a narrow range of 5.0 to 5.6%, and the reflectance is uniformed.

The textures are formed on the silicon substrates for solar cells in the present embodiment, but the present invention is a technique of performing etching on the surface of the substrate by controlling the process gas such as ClF₃ without using plasma. Therefore, suitable results can be obtained also in cases where the present invention is applied to planarization and thinning of substrates for semiconductor devices and so on.

### Embodiment 2

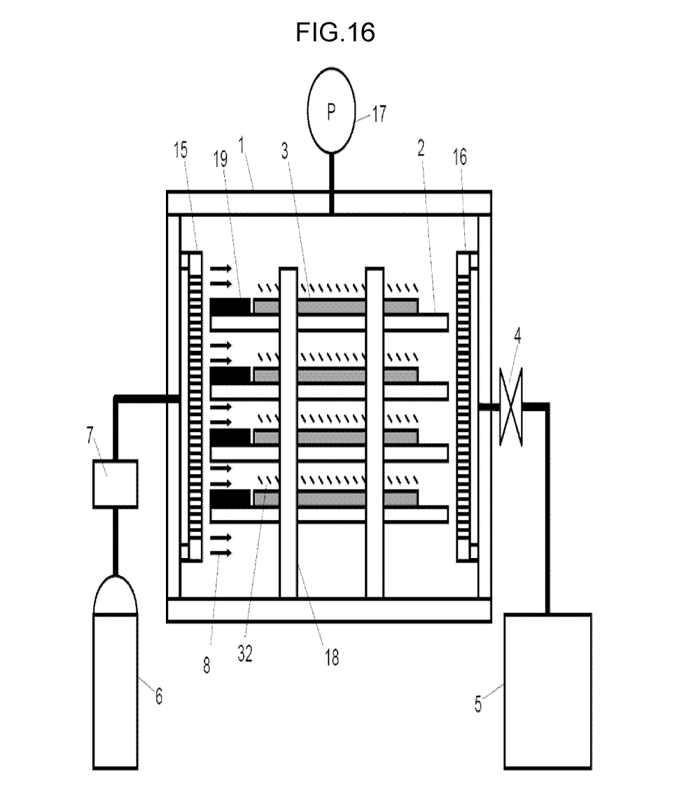

FIG. 16 shows a schematic view of a non-plasma dry etching apparatus according to Embodiment 2 of the present invention. The present embodiment is characterized in that turbulent flow guide plates 32 are installed in addition to the turbulent flow generation mechanism 19 in the above Embodiment 1.

The turbulent flow guide plates 32 are blades having an angle of elevation with respect to the upstream side of the process gas and arranged along the gas flow in the vicinity of the surface of the silicon substrate 3.

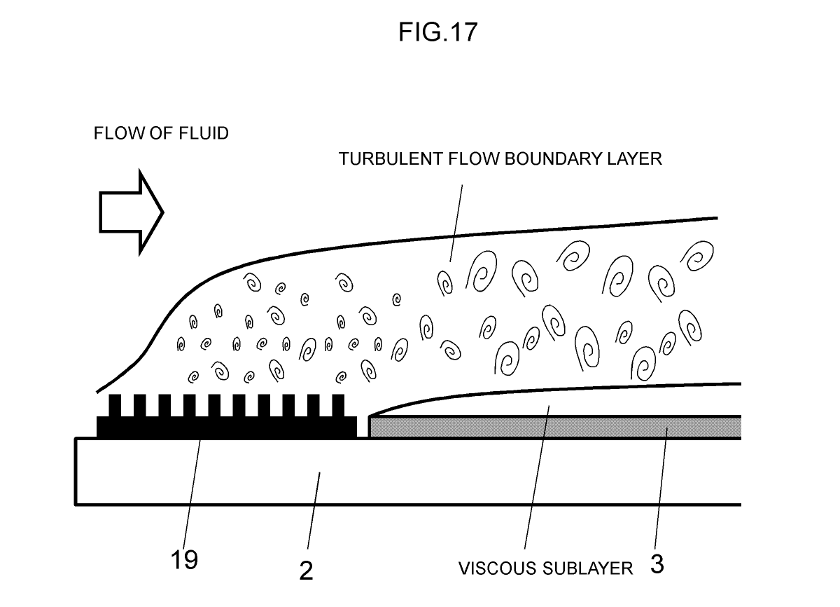

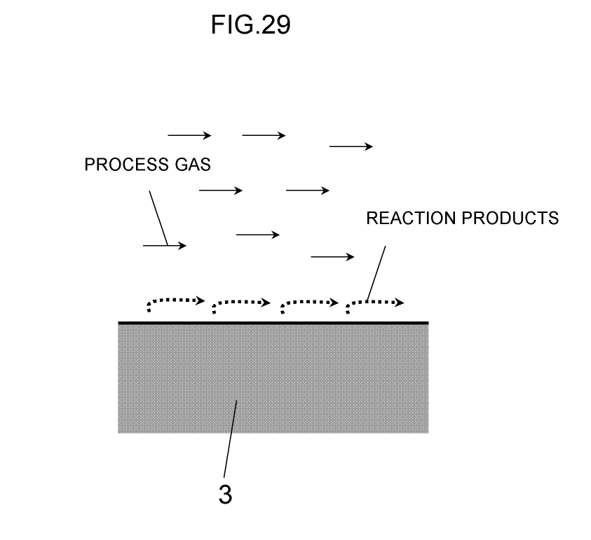

Generally, an extremely small volume of flow similar to a laminar flow called a viscous sublayer as shown in FIG. 17 is formed on the surface of the silicon substrate 3 in a turbulent flow boundary layer, depending on the condition of gas flow. As the flow is similar to the laminar flow inside the viscous sublayer when the viscous sublayer is generated, the gas flows only in the direction in parallel to the silicon substrate 3 as in the above laminar flow boundary layer shown in FIG. 29, so that the movement of substances hardly occurs in a direction perpendicular to the silicon substrate 3. Accordingly, ununiform etching similar to the inside of the above-described laminar flow boundary layer occurs.

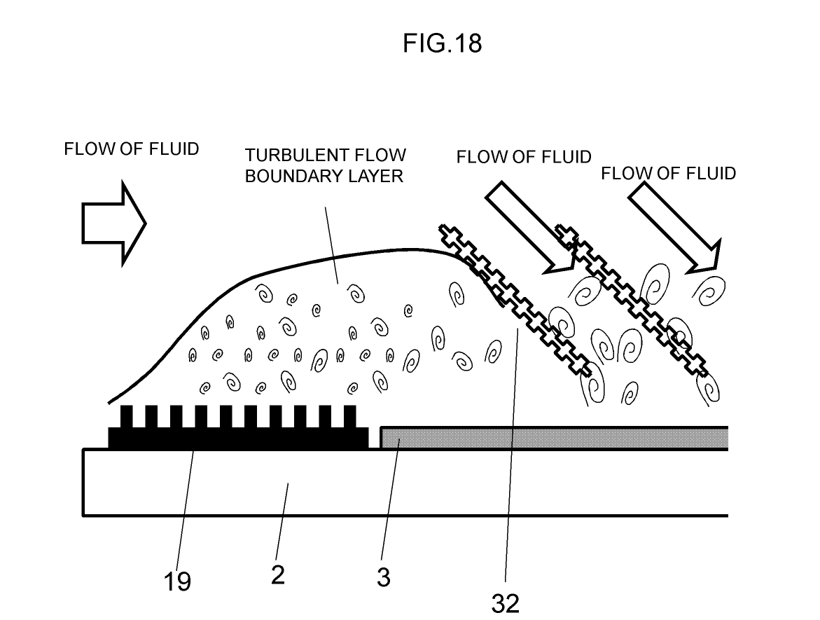

In order to prevent the above, the turbulent flow guide plates 32 are arranged as shown in FIG. 18. The turbulent flow guide plates 32 are blades having an angle of elevation with respect to the upstream side of the process gas in the vicinity of the surface of the silicon substrate 3. The turbulent flow guide plates 32 guide the gas flow outside the boundary layer to the surface of the silicon substrate 3 and agitate the flow on the surface of the silicon substrate 3 by using the flow, thereby preventing the occurrence of the viscous sublayer.

According to the above structure, the process gas 8 which has become turbulent by the turbulent flow generation mechanisms 19 passes through the surfaces of respective silicon substrates 3 in the turbulent state, and the gas flow outside the boundary layer is also guided by the turbulent flow guide plates to the surfaces of the silicon substrates 3 and is agitated thereon. As a result, reaction products generated by the chemical reaction between the process gas and the silicon substrates 3 are interchanged further efficiently, and the uniform etching is promoted over the entire surfaces of the silicon substrates 3.

It is possible that the surfaces of the turbulent flow guide plates 32 have a structure in which the turbulent flow can be efficiently generated, and structures shown in FIG. 6 to FIG. 13 can be applied as well as the above-described turbulent flow generation mechanisms 19.

### Embodiment 3

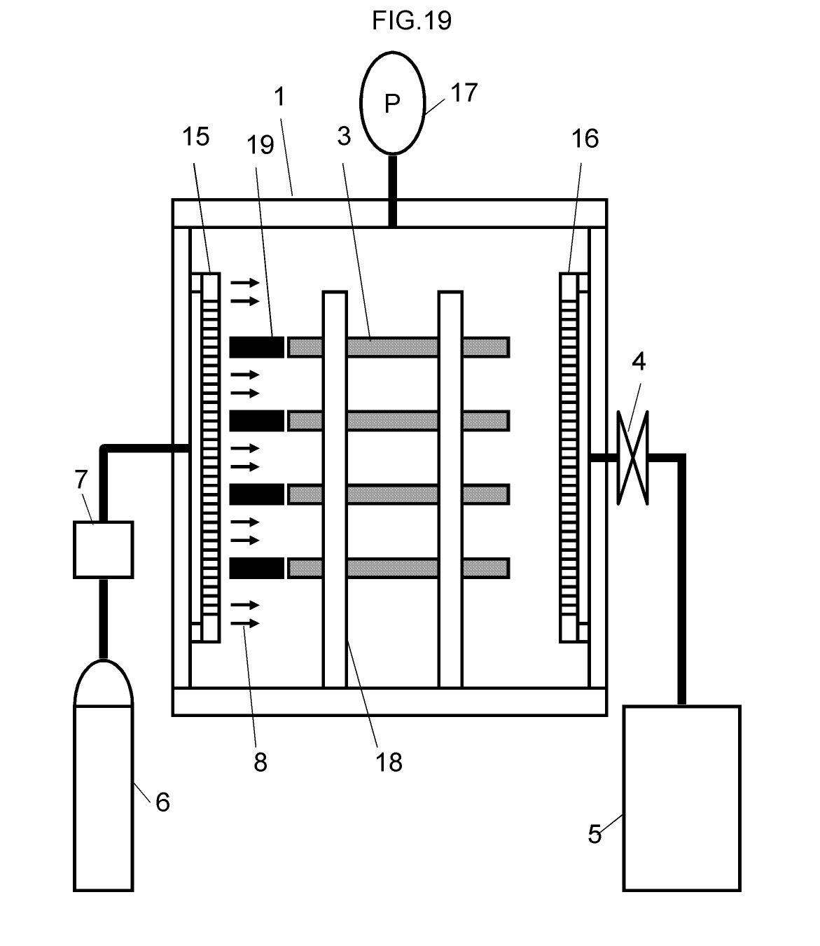

FIG. 19 is a schematic view showing a non-plasma dry etching apparatus according to Embodiment 3 of the present invention.

The present embodiment is characterized in that the stages 2 are removed and the silicon substrates 3 are held in a floating manner as well as effects of the turbulent flow generation mechanism 19 are added to both surfaces of the silicon substrates 3. For example, when the turbulent flow generation mechanism 19 using a blade having projecting portions on front and back surfaces is installed close to an edge portion of the silicon substrate 3 held in the floating manner, turbulent flow boundary layers which are vertically symmetrical are generated on front and back surfaces of the silicon substrate 3, thereby processing both surfaces of the silicon substrate 3 at the same time.

Though the above turbulent flow generation mechanism 19 shown in FIG. 19 is cited as an example in the present embodiment, the same effects can be obtained by the above mechanisms shown in FIG. 6 to FIG. 13 when the turbulent flow generation mechanisms 19 are installed so as to be vertically symmetrical.

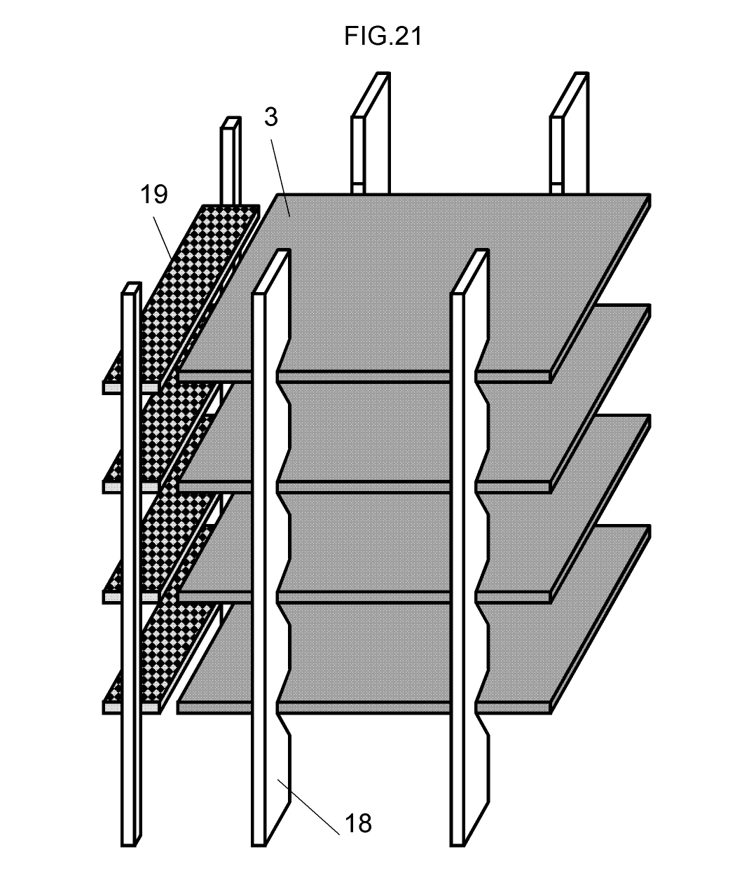

As a mechanism for floating the silicon substrates 3, for example, a substrate holding mechanism 18 as shown in FIG. 21 can be cited as an example. Specifically, groove portions are provided in the substrate holding mechanism 18 to hold the silicon substrate 3 so as to sandwich end portions on both sides thereof. According to the structure, the front surface and the back surface of the silicon substrate 3 can be exposed to the process gas, so that both side processing can be realized.

### Embodiment 4

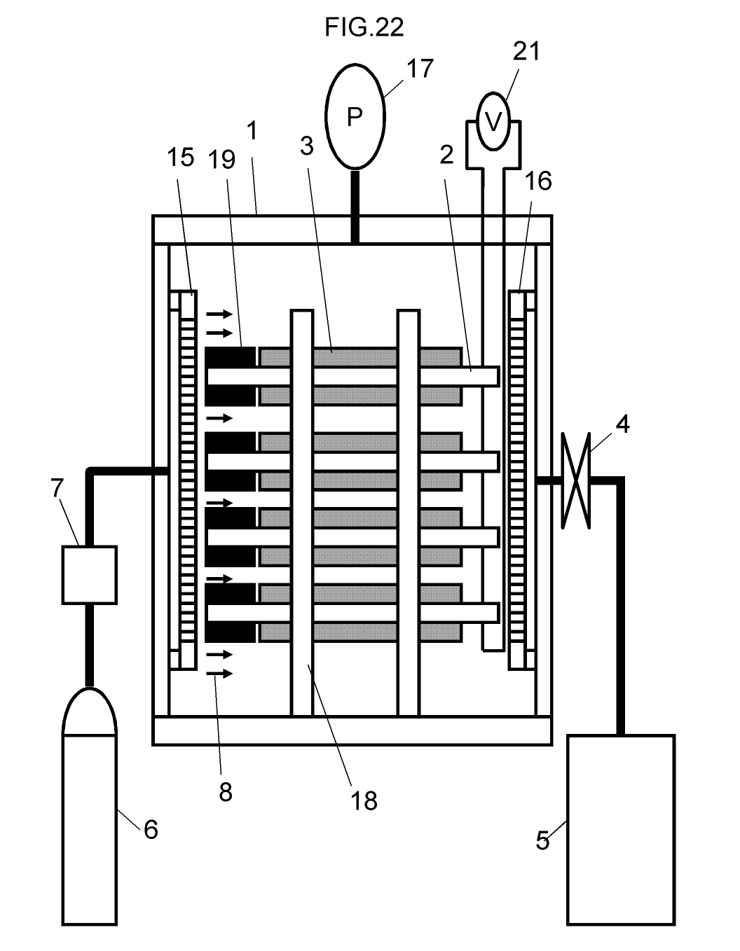

FIG. 22 is a schematic view showing a non-plasma dry etching apparatus according to Embodiment 4 of the present invention.

The stage 2 in Embodiment 1 is allowed to have an electrostatic chuck structure in which front and back surfaces are adsorbent, and the power is fed from a DC power supply 33, thereby adsorbing the silicon substrates 3 respectively on front and back surfaces of the stage 2. According to the structure, twice the number of substrates as compared with Embodiment 1 can be processed, which is a desirable form as an apparatus for mass production.

The non-plasma dry etching apparatus of the invention can respond to the mass production as surfaces of plural substrates can be uniformly etched. Specifically, the present invention can be applied to the formation of the silicon substrates for solar cells and planarization as well as thinning of substrates for semiconductor devices and so on.

What is claimed is:

1. A non-plasma dry etching apparatus comprising:
a reaction chamber which can perform vacuum pumping;
a feed opening connected to the reaction chamber to feed a process gas;
an exhaust opening connected to the reaction chamber to exhaust the gas in the reaction chamber, the exhaust opening arranged to face the feed opening; and
a substrate holding mechanism arranged between the feed opening and the exhaust opening to hold substrates, the substrate holding mechanism including surfaces on which the substrates are placed arranged in parallel to a flow direction of the process gas fed from the feed opening, and
a blade-shaped turbulent flow generation mechanism or one or more wires or bars, provided close to an edge portion near the feed opening of each substrate.

2. The non-plasma dry etching apparatus according to claim 1, further comprising plural turbulent flow guide plates inclined to the feed opening side with respect to surfaces of the substrates provided above the surface of each of the substrates.

3. The non-plasma dry etching apparatus according to claim 1,
wherein the substrate holding mechanism includes plural stages installed at given intervals in the same direction, and
each of the substrates are disposed on the surface of each of the plural stages.

4. The non-plasma dry etching apparatus according to claim 1,
wherein the substrate holding mechanism is configured to hold end portions of the substrates and allow areas of the substrates to float, and includes a mechanism in which the substrates are installed at given intervals in the same direction.

5. The non-plasma dry etching apparatus according to claim 1,
wherein the feed opening is any one of a shower plate having many fine pores, plural slit nozzles and plural spray nozzles arranged in a matrix.

6. The non-plasma dry etching apparatus according to claim 1,
wherein the blade-shaped turbulent flow generation mechanism is any one of
1) a blade having many projections,
2) a blade having many depressions or pores,
3) a blade having projections and depressions or pores alternately,
4) a blade having a corrugated shape and
5) a blade provided with a first wing and a second wing which are alternately arranged at angles in both blades.

7. The non-plasma dry etching apparatus according to claim 2,
wherein the turbulent flow guide plate is any one of
1) a blade having many projections,
2) a blade having many depressions or pores,
3) a blade having projections and depressions or pores alternately,
4) a blade having a corrugated shape and
5) a blade provided with a first wing and second wing which are alternately arranged at angles in both blades.

8. The non-plasma dry etching apparatus according to claim 1,
wherein one or more wires or bars is a wire having a circular cross section.

9. The non-plasma dry etching apparatus according to claim 1,
wherein the one or more wires or bars is a wire having a polygonal cross section.

10. The non-plasma dry etching apparatus according to claim 1,
wherein the process gas includes one or more gases selected from a group including ClF₃, XeF₂, BrF₃ and BrF₅.

11. The non-plasma dry etching apparatus according to claim 10,
wherein the process gas further includes a gas containing oxygen atoms in a molecule.

12. The non-plasma dry etching apparatus according to claim 10,
wherein the process gas further includes a N₂ gas and a noble gas.

13. The non-plasma dry etching apparatus according to claim 1,
wherein a pressure in the reaction chamber is within a range of 1 kPa to 100 kPa.

14. The non-plasma dry etching apparatus according to claim 2,
wherein the substrate holding mechanism includes plural stages installed at given intervals in the same direction, and each of the substrates are disposed on the surface of each of the plural stages.

15. The non-plasma dry etching apparatus according to claim 2,
wherein the substrate holding mechanism is configured to hold end portions of the substrates and allow inside areas of the substrates to float, and includes a mechanism in which the substrates are installed at given intervals in the same direction.

16. The non-plasma dry etching apparatus according to claim 2,
wherein the feed opening is any one of a shower plate having many fine pores, plural slit nozzles and plural spray nozzles arranged in a matrix.

17. The non-plasma dry etching apparatus according to claim 2
wherein the blade-shaped turbulent flow generation mechanism is any one of
1) a blade having many projections,
2) a blade having many depressions or pores,
3) a blade having projections and depressions or pores alternately,
4) a blade having a corrugated shape and
5) a blade provided with a first wing and a second wing which are alternately arranged at angles in both blades.
